(19) United States
(12) Patent Application Publication
(10) Pub. No.: US 2015/0369842 A1
(43) Pub. Date: Dec. 24, 2015

(54) PROBE CARD FOR TESTING SEMICONDUCTOR WAFERS

(71) Applicant: Francis T. McQUADE, Hutto, TX (US)

(72) Inventor: Francis T. McQUADE, Hutto, TX (US)

(21) Appl. No.: 14/309,566

(22) Filed: Jun. 19, 2014

(51) Int. Cl. G01R 1/073

(52) U.S. Cl. CPC G01R 1/07364

(57) ABSTRACT

A probe card is disclosed. The probe card includes a top plate, a disc, a removable plate and multiple micro probes. One of the micro probes includes a curved segment and a linear segment connected to each other at an angle stop. The linear segment is shorter than the curved segment. The top plate includes a set of holes formed therein, and one of the holes is configured to receive the curved segment of the micro probe. The disc includes a set of holes formed therein, and one of the holes is configured to receive the linear segment of the micro probe at the angle stop. The removable plate is removably connected to the disc, and the removable plate includes a set of holes formed therein, wherein one of the holes is configured to receive the linear segment of the micro probe.

### BACKGROUND OF THE INVENTION

1. Technical Field

The present invention relates to probe assemblies in general, and in particular to a probe card that electrically connects a semiconductor wafer to a tester for testing the semiconductor wafer.

2. Description of Related Art

When performing a wafer level test, a probe card containing multiple conductive probes is brought into contact with a chip located on a semiconductor wafer. The probes then transfer various test signals generated by a tester to each integrated circuit within the chip.

During the testing process, the tips of the probes need to be abrasively cleaned on a regular basis in order to provide good electrical contacts. After each cleaning cycle, however, the lengths of the probes are slightly shortened. Once the probes become too short to be useful for testing purposes, the probe card also becomes useless and should be discarded. Since the cost of a new probe card is relatively high, it would be desirable to extend the useful life of a probe card as much as possible.

### SUMMARY OF THE INVENTION

In accordance with a preferred embodiment of the present invention, a probe card includes a top plate, a disc, a removable plate and multiple micro probes. One of the micro probes includes a curved segment and a linear segment connected to each other at an angle stop. The linear segment is shorter than the curved segment. The top plate includes a set of holes formed therein, and one of the holes is configured to receive the curved segment of the micro probe. The disc includes a set of holes formed therein, and one of the holes is configured to receive the linear segment of the micro probe at the angle stop. The removable plate is removably connected to the disc, and the removable plate includes a set of holes formed therein, wherein one of the holes is configured to receive the linear segment of the micro probe.

All features and advantages of the present invention will become apparent in the following detailed written description.

### BRIEF DESCRIPTION OF THE DRAWINGS

The invention itself, as well as a preferred mode of use, further objects, and advantages thereof, will best be understood by reference to the following detailed description of an illustrative embodiment when read in conjunction with the accompanying drawings, wherein:

FIG. 1 is an isometric view of a probe card, in which a preferred embodiment of the present invention is incorporated;

FIG. 2 is a cross-sectional view of the probe card from FIG. 1, in accordance with a preferred embodiment of the present invention;

FIG. 3 shows one micro probe to be used within the probe card from is FIG. 1, in accordance with a preferred embodiment of the present invention;

FIGS. 4a-4b are close-up views of the relevant part of FIG. 2; and

FIGS. 5a-5c show the progression of the usage of the probe card from FIG. 1.

### DETAILED DESCRIPTION OF A PREFERRED EMBODIMENT

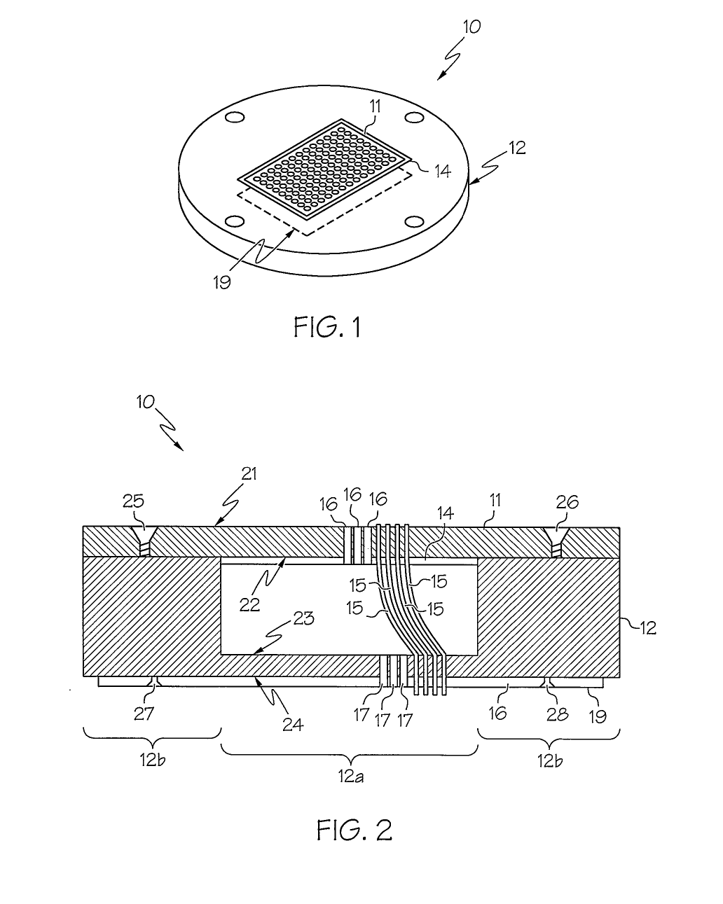

Referring now to the drawings and in particular to FIG. 1, there is depicted an isometric view of a probe card, in which a preferred embodiment of the present invention is incorporated. As shown, a probe card 10 includes a top plate 11, an alignment plate 14, a disc 12 and a removable plate 19. Probe card 10 is designed for vertical probe technology in which probes stand up vertically over a contact site (instead of approaching a contact site at an angle). Top plate 11, alignment plate 14, disc 12 and removable plate 19 contain patterns of holes that correspond to the positions of contact pads located on an integrated circuit to be tested.

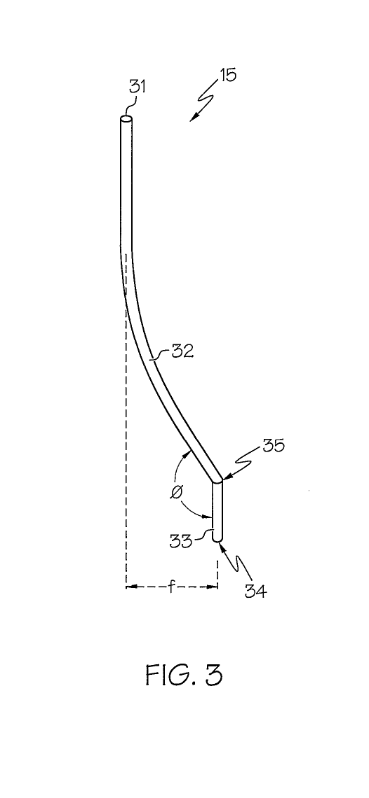

With reference now to FIG. 2, there is illustrated a cross-sectional view of probe card 10, in accordance with a preferred embodiment of the present invention. As shown, probe card 10 includes multiple micro probes 15 going through top plate 11, alignment plate 14, disc 12 and removable plate 19. In the present embodiment, disc 12 is a planar piece of material having a recessed area 12a and a solid area 12b. Recessed area 12a provides a space for receiving alignment plate 14. Recessed area 12a includes a first planar surface 23 and a second planar surface 24. A set of holes 17 are provided through planar surfaces 23, 24 of recessed area 12a. Holes 17 are configured to receive the linear segment of micro probes 15.

Alignment plate 14 lies within recessed area 12a and butting against solid area 12b. Top plate 11 lies across recessed area 12a and extends over solid area 12b. Top plate 11 is removably fixed to an upper surface of solid area 12b via screws 25 and 26. Similarly, removable plate 19 is removably fixed to a lower surface of solid area 12b via screws 27 and 28.

Top plate 11 includes a first planar surface 21, a second planar surface 22 and multiple holes 16 to receive the curved segment of micro probes 15 for providing electrical contacts to a tester (not shown). Alignment plate 14 also has a set of holes matching the set of holes 16 in top plate 11. Alignment plate 14 allows micro probes 15 to be temporarily aligned to top plate 11.

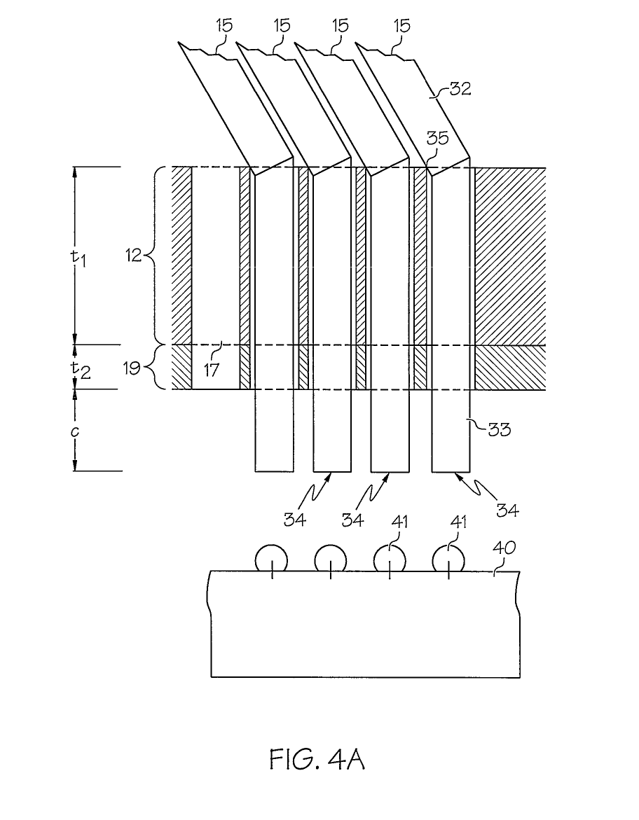

Referring now to FIG. 3, there is illustrated an enlarged view of micro probe 15, in accordance with a preferred embodiment of the present invention. Micro probe 15 includes a curved segment 32 and a linear (straight) segment 33, with curved segment 32 being longer than linear segment 33. Curved segment 32 terminates in a first contact tip 31, and linear segment 33 terminates in a second contact tip 34 that is offset a distance ƒ from first contact tip 31. A portion of curved segment 32 is in a bowed shape curve, and curved segment 32 meets linear segment 33 to form an angle stop 35 with an obtuse angle φ. Curved segment 32 and linear segment 33 are preferably formed from a single piece of wire having a uniform thickness. Angle stop 35 may be used to provide a lower insertion stop when micro probe 15 is placed hole 17 of disc 12 (from FIG. 2).

Preferably, first contact tip 31 is configured to provide electrical contact to electronic test circuitry of a tester, and second contact tip 34 is configured to provide electrical contact to a contact pad located on an integrated circuit. First and second contact tips 31, 34 can be any shape, such as flat, cone shaped, or rounded.

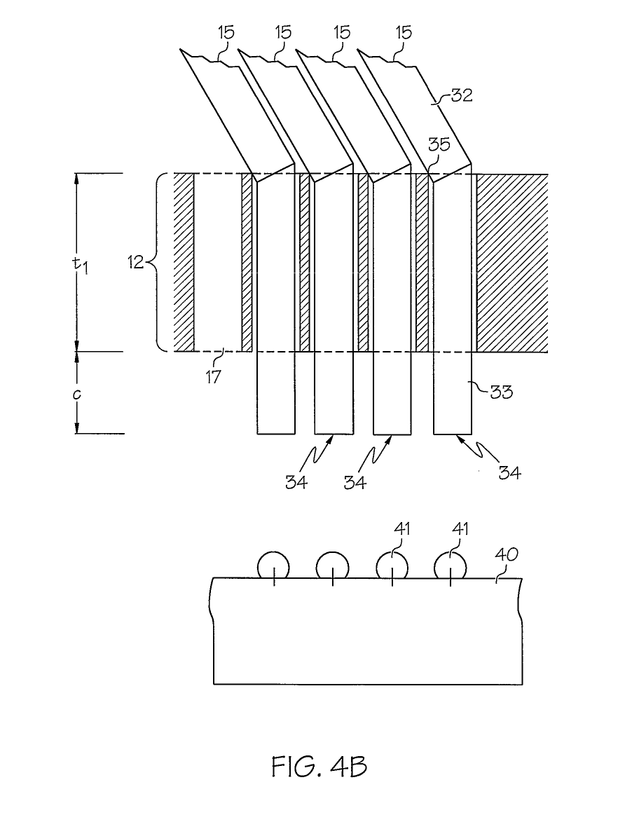

With reference now to FIG. 4, there is illustrated a close-up view of micro probes 15 in disc 12. As shown, micro probes 15 are in an uncompressed condition (i.e., not in contact with bumps 41 on an integrated circuit 40). Each of micro probes 15 has linear segment 33 extending below the lower surface of removable plate 19. When each of micro probes 15 is inserted into one of holes 17, curved segment 32 abuts against the rim proximate to angle stop 35, thereby stopping micro probe 15 from continuing through hole 17. Thus, angle stop 35 on each of micro probes 15 dictates the distance between the lower surface of removable plate 19 and second contact tip 34.

Recessed area 12a of disc 12 has a thickness t₁, and removable plate 19 has a thickness t₂. Along with the length of linear segment 33 of micro probe 15, thickness t₁ and thickness t₂ define the vertical distance micro probes 15 may be compressed (or travel). In FIG. 4a, since linear segment 33 of micro probe 15 extends a distance c below the lower surface of removable plate 19, micro probe 15 may be compressed a maximum distance c. In addition to the purpose of testing, distance c is the optimal length of linear segment 33 to have enough rigidity to withstand the rigors of cleaning cycles between testings. If the length of linear segment 33 is too long, linear segment 33 will bend during the cleaning cycle. If the length of linear segment 33 is too short, linear segment 33 will no longer be suitable to be used for testing.

During the process of wafer level testing, second contact tips 34 of micro probes 15 need to be abrasively cleaned on a regular basis in order to maintain good electrical contacts with bumps 41 on integrated circuit 40. After each cleaning cycle, the lengths of linear segments 33 become slightly shortened (i.e., less than the optimal distance c). Eventually, the lengths of linear segments 33 below removable plate 19 become too short to be useful.

In order correct the above-mentioned problem, removable plate 19 can be removed by loosening screws 27 and 28 (from FIG. 2) such that the optimal distance c for linear segments 33 is restored. Optimal distance c is now provided below the lower surface of disc 12, as shown in FIG. 4b. As a result, the life of probe card 10 having micro probes 15 is prolonged.

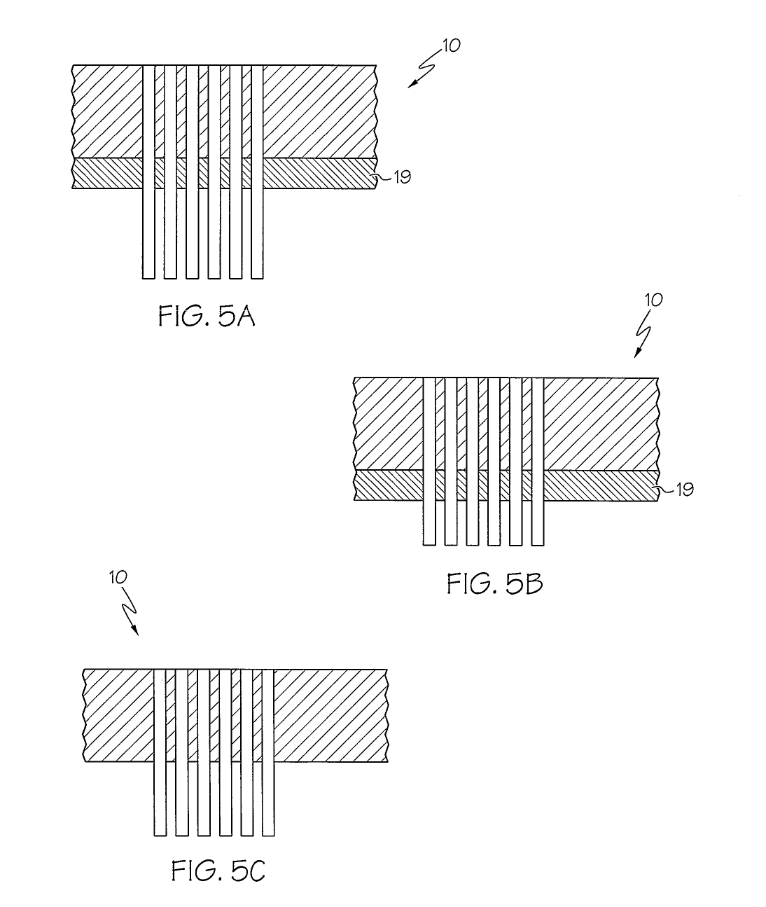

As has been described, the present invention provides an improved probe card for testing integrated circuits on a semiconductor wafer. The progression of the usage of the improved probe card is illustrated in FIGS. 5a-5b. FIG. 5a shows a new probe card (such as probe card 10 from FIG. 1) with new micro probes. After many cycles of abrasive cleaning, the lengths of the micro probes become too short to be suitable for testing, as depicted in FIG. 5b. After a removable plate (such as removable plate 19 from FIG. 2) has been removed from the probe card, the effective lengths of the micro probes are restored, as shown in FIG. 5c, and the probe card can be used for testing again.

While the invention has been particularly shown and described with reference to a preferred embodiment, it will be understood by those skilled in the art that various changes in form and detail may be made therein without departing from the spirit and scope of the invention.

What is claimed is:

1. A probe card comprising:
a plurality of micro probes, wherein one of said micro probes includes a curved segment and a linear segment connected to each other at an angle stop, wherein said linear segment is shorter than said curved segment;
a top plate having a plurality of holes formed therein, wherein one of said holes is configured to receive said curved segment of said one micro probe;
a disc having a plurality of holes formed therein, wherein one of said holes is configured to receive said linear segment of said one micro probe at said angle stop; and
a removable plate removably connected to said disc, wherein said removable plate includes a plurality of holes formed therein, wherein one of said holes is configured to receive said linear segment of said one micro probe.

2. The probe card of claim 1, wherein said curved segment includes a first contact tip configured to provide electrical contact to an electronic test circuitry, wherein said linear segment includes a second contact tip configured to provide electrical contact to a solder bump on a semiconductor wafer.

3. The probe card of claim 1, wherein said curved and linear segments have a uniform thickness.

4. The probe card of claim 1, wherein said curved region is in a bowed shape.

5. The probe card of claim 1, wherein said angle stop is an obtuse angle.

6. The probe card of claim 1, wherein said angle stop forms a sharp bend.

7. The probe card of claim 1, wherein said micro probe is made of a single piece of material.
